(19) United States
(12) Patent Application Publication
(10) Pub. No.: US 2007/0232068 A1
(43) Pub. Date: Oct. 4, 2007

(54) Slurry for touch-up CMP and method of manufacturing semiconductor device

(76) Inventors: Gaku Minamihaba, Yokohama-shi (JP); Nobuyuki Kurashima, Yokohama-shi (JP); Dai Fukushima, Kamakura-shi (JP); Takatoshi Ono, Odawara-shi (JP); Susumu Yamamoto, Oita-shi (JP); Hiroyuki Yano, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/717,045

(22) Filed: Mar. 13, 2007

(30) Foreign Application Priority Data
Mar. 29, 2006 (JP) 2006-092232

(51) Int. Cl. B24D 3/02; H01L 21/461; H01L 21/302

(52) U.S. Cl. 438/692; 51/308; 51/309; 51/307; 438/693

(57) ABSTRACT

A slurry for touch-up CMP is provided, which includes water, colloidal silica having an average primary particle diameter of 5 to 60 nm, unsintered cerium oxide having an average primary particle diameter of 5 to 60 nm, a multivalent organic acid containing no nitrogen atoms, and a nitrogen-containing heterocyclic compound. The slurry has a pH of 8 to 12.

### CROSS-REFERENCE TO RELATED APPLICATIONS

This application is based upon and claims the benefit of priority from prior Japanese Patent Application No. 2006-092232, filed Mar. 29, 2006, the entire contents of which are incorporated herein by reference.

### BACKGROUND OF THE INVENTION

1. Field of the Invention

This invention relates to a slurry for touch-up CMP and a method of manufacturing a semiconductor device.

2. Description of the Related Art

In recent years, in concomitant with a trend to further enhance the performance and integration density of LSI, the wirings thereof are increasingly refined and at the same time, there is a rapid trend to introduce a low-dielectric-constant insulating material (low-k film) having a relative dielectric constant of less than 2.5. In particular, as a damascene wiring is now being formed by CMP using a slurry containing an oxidizing agent, it is desired to suppress, to the greatest possible extent, the corrosion of wiring.

It has been proposed, with a view to prevent the corrosion of Cu, to use a touch-up CMP slurry containing no oxidizing agent (oxidizing acid) (U.S. Patent Application Publication 2005/0090106). This slurry comprises colloidal silica having an average primary particle diameter of 5 to 60 nm, and a multivalent organic acid, wherein the pH thereof is adjusted to the range of 8 to 12. The ratio of the polishing rate of the barrier film to that of the wiring material film described therein is not less than 5 to 1, and the ratio of the polishing rate of the barrier film to that of the insulating film described therein is not less than 10 to 1. However, since the slurry contains no oxidizing agent, the polishing rate of a Cu film used as a wiring material is limited to as low as 20 nm/min or less.

It should be noted that U.S. Pat. No. 5,938,837 describes that it is more preferable to use cerium oxide rather than colloidal silica in order to polish a silicon oxide film at a higher polishing rate. Although it may be possible to secure a sufficient polishing rate while enabling the surface precision to be retained using unsintered cerium oxide particles having an average particle diameter of 10 to 80 nm, no attention is paid therein with respect to the polishing of a metal film.

### BRIEF SUMMARY OF THE INVENTION

A slurry for touch-up CMP according to one aspect of the present invention comprises water; colloidal silica having an average primary particle diameter of 5 to 60 nm; unsintered cerium oxide having an average primary particle diameter of 5 to 60 nm; a multivalent organic acid containing no nitrogen atoms; and a nitrogen-containing heterocyclic compound; the slurry having a pH of 8 to 12.

A method for manufacturing a semiconductor device according to one aspect of the present invention comprises forming an insulating film above a semiconductor substrate; forming a recess in the insulating film; depositing a metal in the recess and above the insulating film to form a metal film; and selectively remove the metal film deposited above the insulating film by CMP using a slurry to remain the metal inside the recess, thereby exposing the insulating film, wherein the slurry having a pH of 8 to 12 and comprising water; colloidal silica having an average primary particle diameter of 5 to 60 nm; unsintered cerium oxide having an average primary particle diameter of 5 to 60 nm; a multivalent organic acid containing no nitrogen atoms; and a nitrogen-containing heterocyclic compound.

### BRIEF DESCRIPTION OF THE SEVERAL VIEWS OF THE DRAWING

FIG. 1 is a cross-sectional view illustrating one step in the method of manufacturing a semiconductor device according to one embodiment of the present invention;

FIG. 2 is a cross-sectional view illustrating a step following the step shown in FIG. 1;

FIG. 3 is a perspective view illustrating a state of CMP; and

FIG. 4 is a cross-sectional view illustrating a step following the step shown in FIG. 2.

### DETAILED DESCRIPTION OF THE INVENTION

Next, embodiments of the present invention will be explained.

The touch-up CMP slurry according to one embodiment of the present invention comprises, as an abrasive grain, colloidal silica having an average primary particle diameter of 5 to 60 nm. Colloidal silica is used because there is little possibility of creating coarse particles (an aggregate of secondary particles) which may cause scratching. In contrast, fumed silica is problematic in that the primary particles thereof vary greatly in size and, at the same time, coarse particles tend to be created, so that it is impossible to control the particle diameter thereof. In the case of alumina, coarse particles are more likely to be formed and, moreover, the polishing rate of the insulating film becomes slow. Even if it is possible to control the average primary particle diameter of fumed silica or alumina, it would be impossible to control the dishing or scratching of the polished surface.

The primary particle diameter of the abrasive grain can be determined by a transmission electronic microscope (TEM). First of all, the greatest length of a particle (dₘ) and the length of the particle orthogonally intersecting an intermediate point of said greatest length (dₚ) are measured; then the average value of these two lengths ((dₘ+dₚ)/2) is defined as the primary particle diameter. This primary particle diameter is calculated for 100 particles and then the average value thereof is calculated to define the average primary particle diameter. If the average primary particle diameter of colloidal silica is less than 5 nm, it would be impossible to polish the metal film and the insulating film at a practical polishing rate of 30 nm/min or more. On the other hand, if the average primary particle diameter of colloidal silica exceeds 60 nm, an unacceptable degree of scratching or dishing of the surface of the metal film would result from the CMP thereof. It should be noted that the degree of association of colloidal silica should preferably be in the range of 1-3.

The content of the aforementioned colloidal silica in the slurry should preferably be in the range of 0.5 to 6 wt %. If the content of the colloidal silica is 0.5 wt % or more, the metal film as well as the insulating film would be enabled to be polished at a polishing rate of as high as 40 nm/min. On the other hand, if the content of the colloidal silica is 6 wt % or less, it would be possible to confine the number of scratches per square centimeter to fewer than 5, and, at the same time, to reduce the dishing to less than 20 nm.

When carrying out touch-up CMP, the metal film deposited on the insulating film is polished away to expose the insulating film while leaving the metal film deposited in the groove constituting the recess. Unless the insulating film thus exposed is polished at the same rate as the polishing rate of metal film on this occasion, defects such as dishing of the metal film or erosion of the insulating film may occur. To avoid these problems, it is necessary, in the case of the touch-up CMP, to enable the insulating film to be polished at the same rate as the metal film including a barrier metal and a wiring material film.

Generally, the polishing of the metal film is performed such that after the surface of the metal film is oxidized by an oxidizing agent, the resultant oxidized layer is removed by abrasive grain. Therefore, the use of an oxidizing agent is considered indispensable for the formulation of a touch-up CMP slurry. Thus, there has been conventionally used an oxidizing agent such as ammonium persulfate, potassium persulfate, hydrogen peroxide, ferric nitrate, diammonium cerium nitrate, iron sulfate, ozone and potassium periodate.

These compounds however tends to promote the corrosion of the metal film and hence promote the dishing of the metal film. Therefore, if the touch-up CMP is performed using a slurry containing no oxidizing agent, the problems to be induced by these oxidizing agents can be overcome. In that case however, it would be impossible to polish the metal film at a practical polishing rate.

It has been found by the present inventors that the unsintered cerium oxide is capable of functioning as an oxidizing agent for a metal without causing corrosion of the metal film. Namely, when a slurry containing the unsintered cerium oxide is permitted to contact a treating surface and then subjected to the load of CMP, the unsintered cerium oxide is enabled to act as an oxidizing agent. Since the unsintered cerium oxide is provided as particles and dispersed in the slurry, the surface of the metal film is oxidized as a certain degree of CMP load is applied to the slurry. If the load of CMP is not applied to the slurry, the unsintered cerium oxide is hardly enabled to function as an oxidizing agent, so that the metal oxide cannot be excessively oxidized. As a result, it is now possible to polish the metal film at a practical polishing rate while preventing the erosion of the metal film. In contrast, in the case of the ordinary oxidizing agent, since the oxidizing agent is dissolved in the solvent, even if the load of CMP is not applied to the slurry, the oxidizing agent is enabled to oxidize the surface of metal film as long as the metal film is kept in contact with the slurry. As a result, the corrosion of the metal film is more likely to be promoted.

It has been recognized, through the electrochemical measurement of Cu and Ti films, that the incorporation of unsintered cerium oxide into the slurry causes changes in current density in the same manner as in the case where hydrogen peroxide is incorporated into the slurry. From this phenomenon, it has been found possible to confirm the oxidation of the surface of metal film by the effect of the unsintered cerium oxide. Moreover, since the incorporation of unsintered cerium oxide is effective in increasing the polishing rate of silicon oxide film, the unsintered cerium oxide is enabled to act also as an abrasive grain for the insulating film. Namely, due to the inclusion of the unsintered cerium oxide, the slurry for the touch-up CMP according to this embodiment is enabled to polish the metal film and the insulating film at a practical polishing rate. It should be noted that in the case of the cerium hydroxide, even if it is provided in an unsintered state, it would be impossible to polish a silicon oxide film at a sufficiently high polishing rate.

The unsintered cerium oxide should be selected from those having an average primary particle diameter of 5 to 60 nm. The average primary particle diameter of the unsintered cerium oxide can be determined in the same manner as in the case of the aforementioned colloidal silica. If the average primary particle diameter of the unsintered cerium oxide is less than 5 nm, it would be impossible to polish the metal film and the insulating film at a practical polishing rate of 30 nm/min or more. On the other hand, if the average primary particle diameter of the unsintered cerium oxide exceeds 60 nm, an unacceptable degree of scratching or dishing of the surface of the metal film would result from the CMP thereof.

The unsintered cerium oxide can be manufactured through a process wherein an aqueous solution of cerium(I) nitrate and aqueous ammonia are agitated vigorously and then the resultant mixture is allowed to age at a temperature of 100° C. or less. Since this cerium oxide is not yet sintered, it is possible to control the average primary particle diameter thereof to fall within the range of 5 to 60 nm and to make the configuration thereof suitable for use in the touch-up CMP. Namely, since the configuration of the unsintered cerium oxide is not angular or relatively smooth, there is little possibility of scratching the surface of metal film.

On the other hand, in the case of the sintered cerium oxide, the average primary particle diameter thereof generally exceeds 100 nm. Because of this, prominent scratching or dishing of the surface of metal film occurs if the sintered cerium oxide is used as a component of the slurry for touch-up CMP. Even if the sintered cerium oxide particles which are relatively large in average primary particle diameter are pulverized, it would be impossible to obtain particles which are uniform in particle diameter and, moreover, the particles thus pulverized would be angular in configuration. Since such angular particles would scratch the surface of metal film, it would be impossible to expect desirable effects even if such angular particles were incorporated into the slurry for touch-up CMP.

The aforementioned unsintered cerium oxide should preferably be incorporated in the slurry at a content of 0.05 to 0.5 wt %. If the content of unsintered cerium oxide is 0.05 wt % or more, it would become possible to polish the metal film and the insulating film at a very high polishing rate of 40 nm/min. On the other hand, if the content of unsintered cerium oxide is 0.5 wt % or less, it would be possible to confine the number of scratches per square centimeter on the surface of metal film in the step of CMP to fewer than 5, and, at the same time, to reduce the dishing to less than 20 nm.

As long as the conditions demanded in terms of the average primary particle diameter are met, zirconium may be added to the unsintered cerium oxide. With respect to the content of zirconium, there is no particular limitation. However, when the power thereof to oxidize the metal as well as the power thereof to polish the insulating film is taken into account, the content of zirconium should preferably be 10 wt % at most. The zirconium-containing unsintered cerium oxide can be manufactured according to the following procedure. Namely, cerium salt and zirconium salt are mixed together to obtain a mixture, which is then mixed with alkali such as aqueous ammonia to obtain the zirconium-containing unsintered cerium oxide.

Since the unsintered cerium oxide having a predetermined size is enabled to act as an oxidizing agent, the slurry for touch-up CMP according to the embodiments of the present invention is not required to contain the conventional oxidizing agent such as hydrogen peroxide which is soluble in a solvent for the slurry. Accordingly, it is now possible, in the case of the slurry for touch-up CMP according to the embodiments of the present invention, to prevent defects such as the corrosion of metal or dishing that may result from the incorporation of the conventional oxidizing agent.

In addition to the aforementioned abrasive grain and oxidizing agent, the slurry for touch-up CMP according to the embodiments of the present invention contains a multivalent organic acid containing no nitrogen atoms, and a nitrogen-containing heterocyclic compound.

The multivalent organic acid containing no nitrogen atoms is capable of enhancing the polishing rate of a metal film, especially a barrier metal. Examples of the multivalent organic acid include tartaric acid, fumaric acid, phthalic acid, maleic acid, oxalic acid, citric acid, malic acid, malonic acid, succinic acid and glutamic acid. These organic acids may be used singly or in combination of two or more kinds.

For the purpose of enhancing the polishing rate of the metal film without accompanying problems such as scratching and dishing, the multivalent organic acid containing no nitrogen atoms may be incorporated in the slurry at a content of 0.001 to 2.0 wt %. More preferably, the content of the multivalent organic acid containing no nitrogen atoms should be in the range of 0.01 to 1.6 wt %.

The nitrogen-containing heterocyclic compound is capable of functioning as an inhibitor to inhibit the corrosion of the metal film, especially a Cu film, examples of the nitrogen-containing heterocyclic compound including heterocyclic compounds formed of a six-membered heteroring or five-membered heteroring, each ring containing at least one nitrogen atom. Examples of the nitrogen-containing heterocyclic compound include quinaldinic acid, quinolinic acid, benzotriazole (BTA), benzoimidazole, 7-hydroxy-5-methyl-1,3,4-triazaindolidine, nicotinic acid and picolionic acid. When these compounds are in contact with the surface of Cu film, the nitrogen atoms constituting the ring coordinate with Cu. Since the rest of the ring structure is enabled to exhibit hydrophobicity, the hydrophobic rings physically adsorb with each other to form a protective film, thus making it possible to inhibit the corrosion of Cu film.

For the purpose of inhibiting the corrosion of the metal film without accompanying problems such as local corrosion and surface abnormality, the nitrogen-containing heterocyclic compound functioning as an inhibitor may be incorporated in the slurry for CMP at a content of 0.01 to 2.0 wt % based on the total weight of the slurry. More preferably, the content of the nitrogen-containing heterocyclic compound should be in the range of 0.05 to 1.0 wt % based on the total weight of the slurry.

A combination of the nitrogen-containing heterocyclic compound and the aforementioned multivalent organic acid containing no nitrogen atoms is used as a polishing rate-adjusting agent. As a result, it is possible to promote the effects of minimizing the scratching and dishing of the metal film and to improve the morphology of the surface of metal film.

The aforementioned components are mixed with water to obtain the slurry for touch-up CMP according to the embodiments of the present invention. As for the kind of water, there is no particular limitation and hence it is possible to use, for example, ion-exchange water and pure water.

However, the pH of the slurry for touch-up CMP according to the embodiments of the present invention is in the range of 8 to 12. If the pH of the slurry is less than 8, the polishing rate of the insulating film in particular decreases and it may become difficult to maintain the balance between the polishing rate of the metal film. On the other hand, if the pH of the slurry exceeds 12, abnormalities, corrosion or scratching of the surface of metal film may occur, thus degrading the effects of the inhibitor. The pH of the slurry is adjusted to the range of 8 to 12 through the addition of a pH adjustor such as potassium hydroxide or aqueous ammonia.

If required, resin particles or a surfactant may be included in the slurry for touch-up CMP according to the embodiments of the present invention. The inclusion of resin particles or a surfactant in the slurry is effective in suppressing the peeling of film or in reducing, to the greatest possible extent, abnormal polishing of the insulating film exhibiting a relative dielectric constant of less than 2.5.

As for the resin particles, it is possible to use, for example, polystyrene, polymethyl methacrylate (PMMA), etc. The primary particle diameter thereof should preferably be in the range of 20 to 500 nm. The resin particles may be included in the slurry at a content of 0.01 to 3.0 wt % in obtaining the effects thereof.

As for the surfactant, it is possible to use, for example, an anionic surfactant, a cationic surfactant and a nonionic surfactant. Examples of the anionic surfactant include, for example, aliphatic soap, sulfate ester, phosphate ester, etc. Examples of the cationic surfactant include, for example, aliphatic amine salt, aliphatic ammonium salt, etc. Examples of the nonionic surfactant includes, for example, acetylene glycol, ethylene oxide adduct thereof, acetylene alcohol, etc. Furthermore, it is also possible to use a silicone-based surfactant, polyvinyl alcohol, cyclodextrin, polyvinyl methylether, hydroxyethyl cellulose, etc. These surfactants may be used singly or in combination of two or more kinds. The content of the surfactant may be in the range of 0.01 to 3.0 wt % based on the total weight of the slurry for CMP in obtaining the effects thereof.

The surfactant may be used in combination with the aforementioned resin particles. In that case, the total amount of resin particles and surfactant should preferably be 3.0 wt % or less based on the total weight of the slurry.

Since the slurry for touch-up CMP according to the embodiments of the present invention contains the unsintered cerium oxide as an oxidizing agent, the components that have been conventionally used as an oxidizing agent is not incorporated in the slurry. Therefore, the problems that have been induced due to the use of the conventional oxidizing agent, such as the corrosion of metal film and the dishing, may be overcome. Especially, since the average primary particle diameter of the unsintered cerium oxide is in the range of 5 to 60 nm, which is the same as the average primary particle diameter of the colloidal silica used as an abrasive grain, it is possible to polish the metal film and the insulating film at a practical polishing rate while suppressing scratching and dishing in the execution of the touch-up CMP. Since defects on the surfaces of the damascene wiring and insulating film formed as described above can be minimized, it is now possible to obtain a semiconductor device having excellent reliability.

### EXAMPLE 1

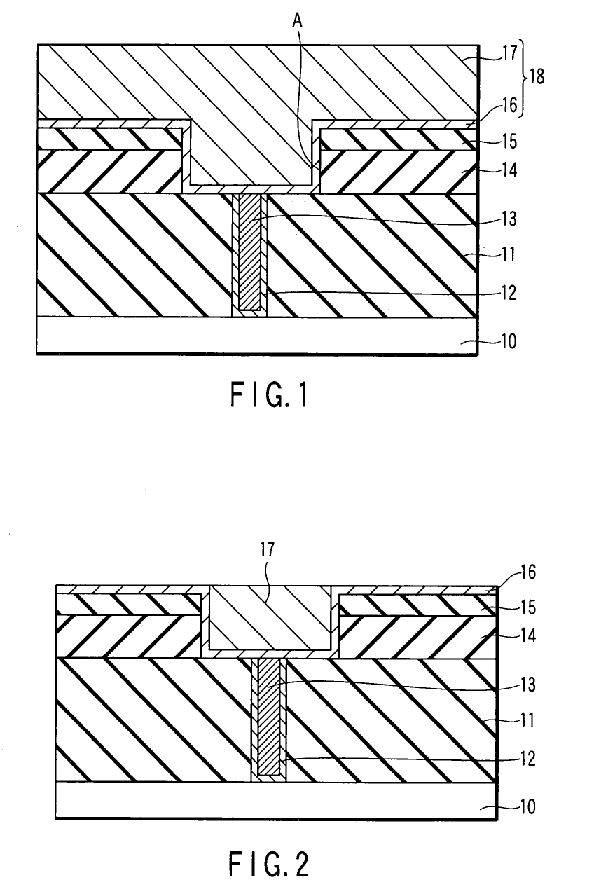

Example 1 will be explained with reference to FIGS. 1 and 2.

First of all, as shown in FIG. 1, an insulating film 11 formed of SiO₂ was deposited on a semiconductor substrate 10 having semiconductor elements (not shown) formed therein and then a plug 13 was formed in the insulating film 11 with a barrier metal 12 being interposed therebetween. The barrier metal 12 was formed using TiN, and the plug 13 was formed using W. Then, a first low-dielectric-constant insulating film 14 and a second low-dielectric-constant insulating film 15 are successively deposited all over the resultant surface to form a laminate insulating film. The first low-dielectric-constant insulating film 14 may be formed using a material having a relative dielectric constant of less than 2.5. For example, it is possible to use at least one selected from the group consisting of a film having a siloxane skeleton such as polysiloxane, hydrogen silsesquioxane, polymethyl siloxane, methylsilsesquioxane, etc.; a film containing, as a major component, an organic resin such as polyarylene ether, polybenzoxazole, polybenzocyclobutene, etc.; and a porous film such as a porous silica film. In this embodiment, the first insulating film 14 was formed from LKD (available from JSR).

The second low-dielectric-constant insulating film 15 deposited on the first low-dielectric-constant insulating film 14 acts as a capping insulating film and may be formed using an insulating material having a larger relative dielectric constant than that of the first low-dielectric-constant insulating film 14. For example, the second low-dielectric-constant insulating film 15 may be formed using at least one insulating material having a relative dielectric constant of 2.5 or more selected from the group consisting of tetraethoxy silane (TEOS), SiC, SiCH, SiCN, SiOC and SiOCH. In this embodiment, the second low-dielectric-constant insulating film 15 was formed using SIOC.

Then, a wiring trench A was formed as a recess in the second low-dielectric-constant insulating film 15 and in the first low-dielectric-constant insulating film 14. Thereafter, a Ti film having a thickness of 2 nm and functioning as a barrier metal 16 and also a Cu film 17 having a thickness of 500 nm were deposited all over the surface according to the ordinary method. By laminating the Cu film 17 on the barrier metal 16, a metal film 18 is constructed. The wiring trench A was formed so as to create a fine wiring having a width of 60 nm and a wide wiring having a width of 75 μm. The fine wirings were formed at a two different density. One of which is isolated state and the other is 50% of coverage. The wide wirings were formed at a two different density. One of which is isolated state and the other is 95% or coverage. It should be noted that the term “isolated portion” means that only one wiring exists in a region of 1 mm². The Cu film 17 constituting part of the metal film 18 was partially removed by CMP (a first polishing) so as to leave the Cu film 17 only in the wiring trench A while partially exposing the surface of the barrier metal 16 as shown in FIG. 2.

Under certain circumstances, the barrier metal 16 may be directly deposited on the first low-dielectric-constant insulating film 14 without necessitating the deposition of the second low-dielectric-constant insulating film 15.

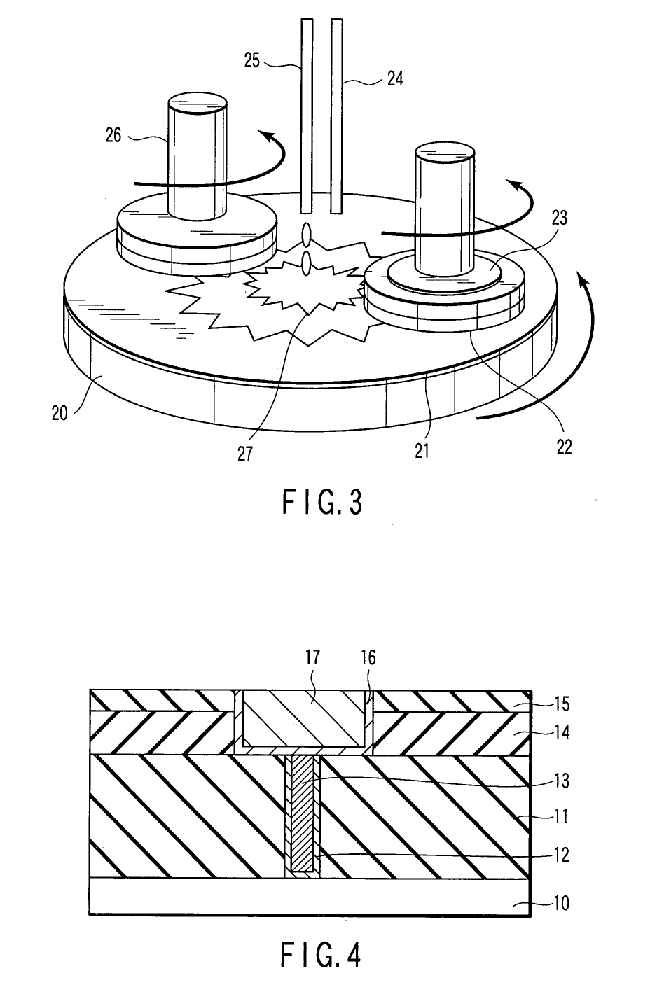

The CMP of the Cu film 17 was performed as follows. Namely, as shown in FIG. 3, first of all, while a turntable 20 having a polishing pad 21 attached thereon was continuously rotated at a speed of 100 rpm, a top ring 23 holding a semiconductor substrate 22 was placed in contact with the polishing pad 21 at a polishing load of 100 g/cm². The rotational speed of the top ring 23 was set to 102 rpm and a slurry 27 was fed from a slurry feed nozzle 25 to the polishing pad 21 at a flow rate of 200 cc/min. It should be noted that FIG. 3 also shows a water feed nozzle 24 and a dresser 26.

The slurry 27 was prepared using CMS7401 and CMS7452 (both available from JSR Co., Ltd.). Specifically, CMS7401, CMS7452 and water were mixed together at a ratio of 1:1:6 to obtain a mixture, to which 2.0 wt % of ammonium persulfate was added as an oxidizing agent. The polishing was continued to considerably exceed the CMP time, which enabled the barrier metal 16 to be exposed as a result of the removal of the Cu film 17, thus performing a 50% over-polishing.

Then, the barrier metal 16 and the Cu film 17 were polished to perform the touch-up polishing, thereby exposing the second low-dielectric-constant insulating film 15 as shown in FIG. 4.

It should be noted that the polishing load of the top ring 23 may be in the range of 10 to 1,000 gf/cm², more preferably 30 to 500 gf/cm². However, in the case where the film to be exposed by this touch-up polishing is an insulating film having a relative dielectric constant of less than 2.5 (low-k film), the polishing load of the top ring 23 should preferably be 100 gf/cm² or less. When the polishing is performed at a load of as low as 100 gf/cm² or less, it is possible to considerably minimize the peeling of the insulating film as well as the deformation of the pattern.

When it is desired to use a low-K film which is relatively weak in mechanical strength, it is also needed to minimize the damages such as the peeling of film and the deformation of pattern. It may be possible to minimize these damages by performing the polishing at a polishing load of as low as 100 gf/cm² or less. In the case however where the slurry to be used contains no oxidizing agent, it has been found difficult to polish all of the wiring material film, the barrier metal film and the insulating film at a practical polishing rate of 30 nm/min or more at a polishing load of 100 gf/cm² or less. In the case of the slurry for touch-up CMP according to the embodiments of the present invention, since the unsintered cerium oxide functioning as an oxidizing agent is included therein, it is now possible to polish all of the wiring material film, the barrier metal film and the insulating film at a practical polishing rate even under a low polishing load of 100 gf/cm² or less.

Further, the rotational speed of the turntable 20 and the top ring 23 may be in the range of 10 to 400 rpm, preferably 30 to 150 rpm. The flow rate of slurry 27 to be fed from the slurry feed nozzle 25 may be in the range of 10 to 1,000 cc/min, preferably 50 to 400 cc/min.

In the preparation of the slurry for CMP for use in the touch-up CMP, the components formulated as follows were at first mixed with pure water to obtain a stock solution. The contents of these components described therein were all based on the total weight of the slurry.

Oxidizing agent: Unsintered cerium oxide (average primary particle diameter: 35 nm)—0.1 wt %

Polishing rate-adjusting agent:

Multivalent organic acid containing no nitrogen atoms (maleic acid)—0.8 wt %

Nitrogen-containing heterocyclic compound (quinolinic acid)—0.1 wt %

To the stock solution prepared as described above was added an abrasive grain to obtain slurries of sample Nos. 1-21. Colloidal silica, fumed silica, colloidal alumina and fumed alumina were prepared for use respectively as the abrasive grain. In this case, the average primary particle diameter of the colloidal silica ranged from 3 to 80 nm and the content thereof ranged from 0.1 to 10 wt %. Other kinds of abrasive grain were respectively selected to have an average primary particle diameter of 30 nm and the content thereof was all set to 2 wt %. It should be noted that the degree of association in each of colloidal silica and colloidal alumina was found 1.5. The secondary particle diameter of each of colloidal silica and colloidal alumina was found as being 200 nm.

In the case of slurry No. 1, 0.2 wt % of hydrogen peroxide was added thereto as an oxidizing agent.

The recipe of each of Nos. 1-21 is summarized in the following Table 1.

TABLE 1

| | | Average | | |
|---|---|---|---|---|
| | | primary particle | Content | |
| No. | Particles | diameter (nm) | (wt %) | H₂O₂ |
| 1 | Colloidal silica | 30 | 2 | Included |
| 2 | Colloidal silica | 5 | 0.1 | None |
| 3 | Colloidal silica | | 0.5 | None |
| 4 | Colloidal silica | | 2 | None |
| 5 | Colloidal silica | | 6 | None |
| 6 | Colloidal silica | | 10 | None |
| 7 | Colloidal silica | 30 | 0.1 | None |
| 8 | Colloidal silica | | 0.5 | None |
| 9 | Colloidal silica | | 2 | None |
| 10 | Colloidal silica | | 6 | None |
| 11 | Colloidal silica | | 10 | None |
| 12 | Colloidal silica | 60 | 0.1 | None |
| 13 | Colloidal silica | | 0.5 | None |
| 14 | Colloidal silica | | 2 | None |
| 15 | Colloidal silica | | 6 | None |
| 16 | Colloidal silica | | 10 | None |
| 17 | Colloidal silica | 3 | 2 | None |
| 18 | Colloidal silica | 80 | 2 | None |
| 19 | Fumed silica | 30 | 2 | None |
| 20 | Colloidal alumina | 30 | 2 | None |
| 21 | Fumed alumina | 30 | 2 | None |

It should be noted that in all of the samples, the pH thereof was respectively adjusted to 10 by adding potassium hydroxide thereto.

Using samples of slurry shown in above Table 1, the touch-up CMP was performed under the aforementioned conditions to investigate the polishing rate of each of the Cu, Ti and SiO₂ films. In determining the polishing rate, solid films of Cu, Ti and SiO₂, each having a film thickness of 2000 nm, were polished for 60 seconds and the polishing rate thereof was calculated based on the measurements of the sheet resistance thereof or based on the optical measurements thereof, in which the polishing rate was evaluated according to the following criteria. When the polishing rate of any of these films was found to be 30 nm/min or more, it was assumed to be acceptable.
◯: 40 nm/min or more
Δ: 30 nm/min to less than 40 nm/min
×: less than 30 nm/min

Further, the dishing, corrosion, surface morphology and scratching of the Cu film were investigated.

The dishing was evaluated as follows. Namely, these films were polished for 60 seconds and then a generated step portion was determined by an atomic force microscope (AFM) and evaluated according to the following criteria.
◯: less than 20 nm
Δ: 20 nm to less than 30 nm
×: 30 nm or more

The corrosion, surface morphology and scratching of the Cu film were measured by a defect-evaluating apparatus (KLA; Tenchol Co., Ltd.) and evaluated based on the number of these defects per cm². In all of these measurements of defects, if the number of defects was less than 20 in a sample, the sample was assumed as being acceptable.
◯: less than 5
Δ: 5 to less than 20
×: not less than 20

The results obtained for each of these slurries are summarized in the following Table 2.

TABLE 2

| | Polishing rate | | | | | | |
|---|---|---|---|---|---|---|---|
| No. | Cu | Ti | SiO₂ | Dishing | Corrosion | Morphology | Scratches |
| 1 | ◯ | ◯ | X | ◯ | X | ◯ | ◯ |
| 2 | Δ | Δ | Δ | ◯ | Δ | ◯ | ◯ |
| 3 | ◯ | ◯ | ◯ | ◯ | ◯ | ◯ | ◯ |
| 4 | ◯ | ◯ | ◯ | ◯ | ◯ | ◯ | ◯ |
| 5 | ◯ | ◯ | ◯ | ◯ | ◯ | ◯ | ◯ |
| 6 | ◯ | ◯ | ◯ | Δ | ◯ | ◯ | Δ |
| 7 | Δ | ◯ | Δ | ◯ | Δ | Δ | Δ |
| 8 | ◯ | ◯ | ◯ | ◯ | ◯ | ◯ | ◯ |
| 9 | ◯ | ◯ | ◯ | ◯ | ◯ | ◯ | ◯ |
| 10 | ◯ | ◯ | ◯ | ◯ | ◯ | ◯ | ◯ |
| 11 | ◯ | ◯ | ◯ | Δ | ◯ | ◯ | Δ |
| 12 | ◯ | ◯ | ◯ | Δ | ◯ | ◯ | Δ |
| 13 | ◯ | ◯ | ◯ | ◯ | ◯ | ◯ | ◯ |
| 14 | ◯ | ◯ | ◯ | ◯ | ◯ | ◯ | ◯ |
| 15 | ◯ | ◯ | ◯ | ◯ | ◯ | ◯ | ◯ |
| 16 | ◯ | ◯ | ◯ | Δ | ◯ | Δ | Δ |
| 17 | X | Δ | X | Δ | Δ | Δ | X |
| 18 | ◯ | ◯ | ◯ | X | ◯ | ◯ | X |
| 19 | ◯ | ◯ | ◯ | X | ◯ | ◯ | X |
| 20 | ◯ | X | X | X | ◯ | X | X |
| 21 | ◯ | X | X | X | ◯ | X | X |

As shown in above Table 2, the slurries of Nos. 2-16 wherein hydrogen peroxide was not included and colloidal silica having a predetermined size was included therein were all found to exhibit the results falling within the acceptable range. Especially, in the case of slurries (Nos. 3-5, 8-10 and 13-15) wherein the content of the colloidal silica used as abrasive particles was falling within the range of 0.5 to 6 wt %, the Cu, Ti and SiO₂ films were all enabled to polish at a polishing rate of 40 nm/min or more. Moreover, it was possible to prominently reduce the defects such as dishing.

In the case of slurry No. 1, since hydrogen peroxide was included therein, the polishing rate of the SiO₂ film was found unacceptable. The reason for this may be assumably attributed to the phenomenon that cerium oxide was dissolved by hydrogen peroxide, thereby making the cerium oxide unavailable for the polishing of the SiO₂ film. Further, in the case of slurry No. 1, corrosion of the Cu film was found to occur to an unacceptable degree.

In the case of the slurry where the average primary particle diameter of colloidal silica was relatively small (No. 17), it was impossible to polish the Cu, Ti and SiO₂ films all at a polishing rate of 30 nm/min or more. On the other hand, in the case of the slurry where the average primary particle diameter of colloidal silica was relatively large (No. 18), it was impossible to confine the dishing and scratching to an acceptable range.

In the case of the slurry where abrasive grains other than colloidal silica was included therein even if the average primary particle diameter of the abrasive grain was within a predetermined acceptable range (Nos. 19, 20 and 21), it was impossible to confine the dishing and scratching to an acceptable range. Especially in the case where alumina particles were used as an abrasive grain, the polishing rate of the Ti and SiO₂ films degraded as seen from the slurries of Nos. 20 and 21.

### EXAMPLE 2

In this example, the influence of cerium-based particles was investigated.

First of all, a stock solution was prepared according to the following recipe.

Abrasive grain:

Colloidal silica (average primary particle diameter: 30 nm; and association degree: 2)—2 wt %

Polishing rate-adjusting agent:

Multivalent organic acid containing no nitrogen atoms (citric acid)—0.5 wt %

Nitrogen-containing heterocyclic compound (quinaldinic acid)—0.3 wt %

To the stock solution prepared as described above were added various kinds of cerium-based particles to obtain slurries of sample Nos. 22-40. Unsintered cerium oxide, unsintered cerium hydroxide and sintered cerium oxide were prepared for use respectively as the cerium-based particles. In this case, the average primary particle diameter of the unsintered cerium oxide varied from 2 to 80 nm and the content thereof varied from 0.01 to 1 wt %. The average primary particle diameter of the unsintered cerium hydroxide was 25 nm and the average primary particle diameter of the sintered cerium oxide was 120 nm.

The recipe of each of Nos. 22-40 is summarized in the following Table 3.

TABLE 3

| | | Average | |
|---|---|---|---|
| | | primary particle | Content |
| No. | Kinds of cerium | diameter (nm) | (wt %) |
| 22 | Unsintered cerium oxide | 2 | 0.1 |
| 23 | Unsintered cerium oxide | 5 | 0.01 |
| 24 | Unsintered cerium oxide | | 0.05 |
| 25 | Unsintered cerium oxide | | 0.1 |
| 26 | Unsintered cerium oxide | | 0.5 |
| 27 | Unsintered cerium oxide | | 1 |
| 28 | Unsintered cerium oxide | 25 | 0.01 |
| 29 | Unsintered cerium oxide | | 0.05 |
| 30 | Unsintered cerium oxide | | 0.1 |
| 31 | Unsintered cerium oxide | | 0.5 |
| 32 | Unsintered cerium oxide | | 1 |
| 33 | Unsintered cerium oxide | 60 | 0.01 |
| 34 | Unsintered cerium oxide | | 0.05 |
| 35 | Unsintered cerium oxide | | 0.1 |
| 36 | Unsintered cerium oxide | | 0.5 |
| 37 | Unsintered cerium oxide | | 1 |
| 38 | Unsintered cerium oxide | 80 | 0.1 |
| 39 | Unsintered cerium | 25 | 0.1 |
| | hydroxide | | |
| 40 | Sintered cerium oxide | 120 | 0.1 |

It should be noted that in all of the samples, the pH thereof was respectively adjusted to 10 by adding potassium hydroxide thereto. Further, a sample of No. 41 was prepared using only the stock solution without adding cerium-based particles thereto.

The touch-up CMP was performed using slurry samples shown in above Table 3 under the same conditions as those of Example 1 to investigate the polishing rate of the Cu, Ti and SiO₂ films. Further, the dishing, corrosion, surface morphology and scratching of the Cu film were investigated. The results of the investigation are summarized in the following Table 4 based on the same criteria as described above.

TABLE 4

| | Polishing rate | | | | | | |
|---|---|---|---|---|---|---|---|
| No. | Cu | Ti | SiO₂ | Dishing | Corrosion | Morphology | Scratches |
| 22 | X | Δ | X | Δ | Δ | X | X |
| 23 | ◯ | Δ | Δ | ◯ | ◯ | ◯ | ◯ |
| 24 | ◯ | ◯ | ◯ | ◯ | ◯ | ◯ | ◯ |
| 25 | ◯ | ◯ | ◯ | ◯ | ◯ | ◯ | ◯ |
| 26 | ◯ | ◯ | ◯ | ◯ | ◯ | ◯ | ◯ |
| 27 | ◯ | ◯ | ◯ | Δ | ◯ | Δ | Δ |
| 28 | ◯ | Δ | Δ | ◯ | ◯ | ◯ | ◯ |
| 29 | ◯ | ◯ | ◯ | ◯ | ◯ | ◯ | ◯ |
| 30 | ◯ | ◯ | ◯ | ◯ | ◯ | ◯ | ◯ |
| 31 | ◯ | ◯ | ◯ | ◯ | ◯ | ◯ | ◯ |
| 32 | ◯ | ◯ | ◯ | Δ | ◯ | Δ | Δ |
| 33 | ◯ | Δ | Δ | ◯ | ◯ | ◯ | ◯ |
| 34 | ◯ | ◯ | ◯ | ◯ | ◯ | ◯ | ◯ |
| 35 | ◯ | ◯ | ◯ | ◯ | ◯ | ◯ | ◯ |
| 36 | ◯ | ◯ | ◯ | ◯ | ◯ | ◯ | ◯ |
| 37 | ◯ | ◯ | ◯ | Δ | ◯ | Δ | Δ |
| 38 | ◯ | ◯ | ◯ | X | ◯ | X | X |
| 39 | ◯ | X | X | ◯ | ◯ | X | X |
| 40 | ◯ | ◯ | ◯ | X | ◯ | X | X |
| 41 | X | Δ | X | Δ | Δ | Δ | X |

As shown in above Table 4, the slurries of Nos. 23-37 wherein unsintered cerium oxide having an average primary particle diameter of 5 to 60 nm was included therein were all found to exhibit the results falling within the acceptable range. Especially in the case of slurries (Nos. 24-26, 29-31 and 34-36) wherein the content of the unsintered cerium oxide ranged from 0.05 to 0.5 wt %, the Cu, Ti and SiO₂ films were all enabled to polish at a polishing rate of 40 nm/min or more. Moreover, it was possible to prominently reduce the dishing, morphology and scratching of the Cu film.

In the case of the slurry where the average primary particle diameter of the unsintered cerium oxide was relatively small (No. 22), it was impossible to polish the Cu, Ti and SiO₂ films all at a polishing rate of 30 nm/min or more. On the other hand, in the case of the slurry where the average primary particle diameter of the unsintered cerium oxide was relatively large (No. 38), it was impossible to confine the dishing, morphology and scratching of the metal film to an acceptable range.

In the case of the slurry where unsintered cerium hyroxide was included therein even if the average primary particle diameter thereof was within a predetermined acceptable range (No. 39), the polishing rate of the Ti and SiO₂ films degraded. Moreover, the resultant film deteriorated in terms of morphology and scratching.

In the case of the sintered cerium oxide, since the primary particle diameter thereof cannot be controlled, the particles of the sintered cerium oxide were as large as 120 nm. In the case of the slurry where the sintered cerium oxide having such a large primary particle diameter was included therein (No. 40), the resultant film deteriorated to an unacceptable degree in terms of dishing, morphology and scratching.

In the case of the slurry where no cerium-based particles were included therein (No. 41), it was impossible to polish the Cu and SiO₂ films at a practical polishing rate.

For reference, the sintered cerium oxide used in sample No. 40 was pulverized by ball mill, thereby trying to prepare particles having an average primary particle diameter of 5 to 60 nm. However, the average primary particle diameter of the particles thus obtained was found to fall within a wide range of about 30 to 120 nm and the configuration thereof was angular or not smooth. It was determined that because of this configuration, it was impossible to obtain desired effects even if the sintered cerium oxide thus pulverized was incorporated into the slurry for touch-up CMP.

### EXAMPLE 3

Slurry samples Nos. 42-46 were prepared according to the same recipe as used in sample No. 30 of Example 2 except that the multivalent organic acid containing no nitrogen atoms was changed to those shown in the following Table 5. Further, slurry sample No. 47 was prepared according to the same recipe as used in sample No. 30 of Example 2 except that citric acid was not incorporated therein.

TABLE 5

| | Multivalent |
|---|---|
| No. | organic acids |
| 42 | Maleic acid |
| 43 | Oxalic acid |
| 44 | Malic acid |
| 45 | Malonic acid |
| 46 | Acetic acid |

The organic acids used in Nos. 42-45 are multivalent organic acid and the organic acid used in No. 46 is monovalent organic acid.

The touch-up CMP was performed using slurry samples shown in above Table 5 under the same conditions as those of Example 1 to investigate the polishing rate of the Cu, Ti and SiO₂ films. Further, the dishing, corrosion, surface morphology and scratching of the Cu film were investigated. The results of the investigation are summarized in the following Table 6 based on the same criteria as described above.

TABLE 6

| | Polishing rate | | | | | | |
|---|---|---|---|---|---|---|---|
| No. | Cu | Ti | SiO₂ | Dishing | Corrosion | Morphology | Scratches |
| 42 | ◯ | ◯ | ◯ | ◯ | ◯ | ◯ | ◯ |
| 43 | ◯ | ◯ | ◯ | ◯ | ◯ | ◯ | ◯ |
| 44 | ◯ | ◯ | ◯ | ◯ | ◯ | ◯ | ◯ |
| 45 | ◯ | ◯ | ◯ | ◯ | ◯ | ◯ | ◯ |
| 46 | ◯ | ◯ | ◯ | X | ◯ | X | Δ |
| 47 | ◯ | X | ◯ | X | Δ | X | Δ |

As shown in above Table 6, it will be recognized from the results of sample Nos. 42-45 that as long as a multivalent organic acid containing no nitrogen atoms is incorporated in the slurry, irrespective of the kind thereof, it is possible to obtain almost the same results. In contrast, in the case of a monovalent organic acid, it is impossible to confine the dishing and surface morphology to an acceptable range as shown in sample No. 46. Further, in the case where no organic acid was incorporated in the slurry (No. 47), it was impossible to polish the Ti film at a polishing rate of 30 nm/min or more and the resultant film was found unacceptable in terms of dishing and surface morphology.

### EXAMPLE 4

Slurry samples Nos. 48-50 were prepared according to the same recipe as used in sample No. 30 of Example 2 except that the nitrogen-containing heterocyclic compound was changed to those shown in the following Table 7. Further, slurry sample No. 51 was prepared according to the same recipe as used in sample No. 30 of Example 2 except that quinaldinic acid was not incorporated therein.

TABLE 7

| | Nitrogen-containing |
|---|---|
| | heterocyclic |
| No. | compounds |
| 48 | Quinolinic acid |
| 49 | Benzoimidazole |
| 50 | BTA |

The touch-up CMP was performed using slurry samples shown in above Table 7 under the same conditions as those of Example 1 to investigate the polishing rate of the Cu, Ti and SiO₂ films. Further, the dishing, corrosion, surface morphology and scratching of the Cu film were investigated. The results of the investigation are summarized in the following Table 8 based on the same criteria as described above.

TABLE 8

| | Polishing rate | | | | | | |
|---|---|---|---|---|---|---|---|
| No. | Cu | Ti | SiO₂ | Dishing | Corrosion | Morphology | Scratches |
| 48 | ◯ | ◯ | ◯ | ◯ | ◯ | ◯ | ◯ |
| 49 | ◯ | ◯ | ◯ | ◯ | ◯ | ◯ | ◯ |
| 50 | ◯ | ◯ | ◯ | ◯ | ◯ | ◯ | ◯ |
| 51 | ◯ | ◯ | ◯ | X | X | Δ | X |

As shown in above Table 8, it will be recognized from the results of sample Nos. 48-50 that as long as a nitrogen-containing heterocyclic compound is incorporated in the slurry, irrespective of the kind thereof, it is possible to obtain almost the same results. In contrast, in the case of the slurry where no kind of nitrogen-containing heterocyclic compound is incorporated therein (No. 51), it is impossible to confine the Cu corrosion, dishing and scratching to an acceptable range.

### EXAMPLE 5

Slurry samples Nos. 52-55 were prepared according to the same recipe as used in sample No. 30 of Example 2 except that the pHs of the slurries were changed to those shown in the following Table 9.

TABLE 9

| No. | pH |
|---|---|
| 52 | 7 |
| 53 | 8 |
| 54 | 12 |
| 55 | 13 |

The pHs of the slurries were respectively adjusted by adding potassium hydroxide thereto.

The touch-up CMP was performed using slurry samples shown in above Table 9 under the same conditions as those of Example 1 to investigate the polishing rate of the Cu, Ti and SiO₂ films. Further, the dishing, corrosion, surface morphology and scratching of the Cu film were investigated. The results of the investigation are summarized in the following Table 10 based on the same criteria as described above.

TABLE 10

| | Polishing rate | | | | | | |
|---|---|---|---|---|---|---|---|
| No. | Cu | Ti | SiO₂ | Dishing | Corrosion | Morphology | Scratches |
| 52 | ◯ | Δ | X | X | X | Δ | ◯ |
| 53 | ◯ | ◯ | ◯ | ◯ | ◯ | ◯ | ◯ |
| 54 | ◯ | ◯ | ◯ | ◯ | ◯ | ◯ | ◯ |
| 55 | X | Δ | ◯ | Δ | X | Δ | X |

As shown in above Table 10, it will be recognized from the results of sample Nos. 53 and 54 that as long as the pH of the slurry is in the range of 8 to 12, it is possible to obtain almost the same results. When the pH of the slurry is less than 8 (No. 52), the polishing rate of the SiO₂ film becomes slow and the resultant film surface would deteriorate to an unacceptable degree in terms of the dishing and corrosion of the Cu film. On the other hand, when the pH of the slurry exceeds 12 (No. 55), the polishing rate of the Cu film would deteriorate and the resultant Cu film surface would become unacceptable in terms of corrosion and scratching.

### EXAMPLE 6

First of all, a structure as shown in FIG. 2 was obtained according to the same procedure as described in Example 1 except that the second low-dielectric-constant insulating film 15 was not provided therein. In this example, the barrier metal 16 was removed by performing the touch-up CMP, thereby exposing the first low-dielectric-constant insulating film 14 having a relative dielectric constant of less than 2.5.

The slurry to be used in the touch-up CMP was prepared by incorporating resin particles and a surfactant into slurry sample No. 30 of Example 2. More specifically, polystyrene particles having a primary particle diameter of 200 nm were added to the slurry at a content of 0.5 wt % based on the total weight of the slurry to prepare slurry sample No. 56. Further, acetylene diol-based nonions were added to the slurry at a content of 0.5 wt % based on the total weight of the slurry to prepare slurry sample No. 57.

Using the slurry samples thus obtained, the touch-up CMP was performed at a polishing load of 100 gf/cm² to remove the barrier metal film 16.

When any of these slurry samples was used, it was possible to polish the Cu, Ti and SiO₂ films all at a polishing rate of 40 nm/min or more. Moreover, substantially no peeling of the first low-dielectric-constant insulating film 14 or abnormal polishing was recognized.

In the foregoing examples, Cu was used as a wiring material and Ti was used as a barrier metal. However, the kinds of metal which make it possible to realize the effects of the slurry according to the embodiment of the present invention are not limited to these metals.

The slurry for touch-up CMP according to the embodiments of the present invention is applicable to a structure comprising Cu, Al, W, Ti, TiN, Ta, TaN, V, Mo, Ru, Zr, Mn, Ni, Fe, Ag, Mg, Si, Co, Pd or Rh, or to a structure of a laminate structure comprising such metals, or to a structure wherein a barrier metal does not substantially exist therein. It is expected that the slurry for touch-up CMP according to the embodiments of the present invention is enabled to exhibit almost the same effects when forming a damascene wiring through the polishing of almost any kind of metal.

As described above, according to one embodiment of the present invention, it is possible to provide a slurry for touch-up CMP, which is capable of polishing a metal film without substantially causing corrosion, scratching and dishing thereof. According to another embodiment of the present invention, it is possible to provide a method of manufacturing a semiconductor device of high reliability which is capable of forming a damascene wiring through the polishing of a metal film at a practical polishing rate without substantially causing corrosion, scratching and dishing thereof.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A slurry for touch-up CMP comprising:
water;
colloidal silica having an average primary particle diameter of 5 to 60 nm;
unsintered cerium oxide having an average primary particle diameter of 5 to 60 nm;
a multivalent organic acid containing no nitrogen atoms; and
a nitrogen-containing heterocyclic compound;
the slurry having a pH of 8 to 12.

2. The slurry according to claim 1, wherein the colloidal silica is included in the slurry at a content of 0.5 to 6 wt %.

3. The slurry according to claim 1, wherein the unsintered cerium oxide is included in the slurry at a content of 0.05 to 0.5 wt %.

4. The slurry according to claim 1, wherein the unsintered cerium oxide includes therein zirconium.

5. The slurry according to claim 4, wherein zirconium is included in the unsintered cerium oxide at a content of not more than 10% based on a weight of the unsintered cerium oxide.

6. The slurry according to claim 1, wherein the multivalent organic acid containing no nitrogen atoms is selected from the group consisting of tartaric acid, fumaric acid, phthalic acid, maleic acid, oxalic acid, citric acid, malic acid, malonic acid, succinic acid and glutamic acid.

7. The slurry according to claim 1, wherein the multivalent organic acid containing no nitrogen atoms is included in the slurry at a content of 0.001 to 2.0 wt %.

8. The slurry according to claim 1, wherein the nitrogen-containing heterocyclic compound is selected from the group consisting of quinaldinic acid, quinolinic acid, benzotriazole, benzoimidazole, 7-hydroxy-5-methyl-1,3,4-triazaindolidine, nicotinic acid and picolionic acid.

9. The slurry according to claim 1, wherein the nitrogen-containing heterocyclic compound is included in the slurry at a content of 0.01 to 2.0 wt %.

10. The slurry according to claim 1, further comprising resin particles.

11. The slurry according to claim 1, further comprising a surfactant.

12. A method for manufacturing a semiconductor device, comprising
forming an insulating film above a semiconductor substrate;
forming a recess in the insulating film;
depositing a metal in the recess and above the insulating film to form a metal film; and
selectively remove the metal film deposited above the insulating film by CMP using a slurry to remain the metal inside the recess, thereby exposing the insulating film, wherein the slurry having a pH of 8 to 12 and comprising water; colloidal silica having an average primary particle diameter of 5 to 60 nm; unsintered cerium oxide having an average primary particle diameter of 5 to 60 nm; a multivalent organic acid containing no nitrogen atoms; and a nitrogen-containing heterocyclic compound.

13. The method according to claim 12, wherein the metal film comprises a barrier metal and a Cu film.

14. The method according to claim 13, wherein the barrier metal, the Cu film and the insulating film are polished by the slurry at a rate of 30 nm/min or more.

15. The method according to claim 12, wherein the colloidal silica is included in the slurry at a content of 0.5 to 6 wt %.

16. The method according to claim 12, wherein the unsintered cerium oxide is included in the slurry at a content of 0.05 to 0.5 wt %.

17. The method according to claim 12, wherein the insulating film is formed of a low-dielectric-constant insulating material having a relative dielectric constant of less than 2.5, and the CMP is performed at a load of 100 gf/cm² or less.

18. The method according to claim 17, wherein the low-dielectric-constant insulating material having a relative dielectric constant of less than 2.5 is selected from the group consisting of polysiloxane, hydrogen silsesquioxane, polymethyl siloxane, methylsilsesquioxane, polyarylene ether, polybenzoxazole, polybenzocyclobutene and a porous silica film.

19. The method according to claim 17, wherein the slurry further comprises resin particles.

20. The method according to claim 17, wherein the slurry further comprises a surfactant.
